(19) United States
(12) Patent Application Publication
(10) Pub. No.: US 2025/0081855 A1
(43) Pub. Date: Mar. 6, 2025

(54) ONE-DIMENSIONAL METAL-DOPED PEROSKITE-TYPE NIOBATE PIEZOELECTRIC MATERIAL AND PREPARATION METHOD AND USE THEREOF, FLEXIBLE ACOUSTIC SENSITIVE DEVICE AND PREPARATION METHOD THEREOF

(71) Applicant: INSTITUTE OF CHEMISTRY, CHINESE ACADEMY OF SCIENCES, Beijing (CN)

(72) Inventors: Lihong LI, Beijing (CN); Zhongyuan XIANG, Beijing (CN); Yanlin SONG, Beijing (CN)

(73) Assignee: INSTITUTE OF CHEMISTRY, CHINESE ACADEMY OF SCIENCES, Beijing (CN)

(21) Appl. No.: 18/273,593

(22) PCT Filed: Oct. 21, 2022
(86) PCT No.: PCT/CN2022/126703

§ 371 Date: Jul. 21, 2023

(30) Foreign Application Priority Data
Mar. 17, 2022 (CN) 202210262564.7
Mar. 18, 2022 (CN) 202210267872.9
Mar. 18, 2022 (CN) 202210270270.9

(51) Int. Cl. H10N 30/853; H10N 30/093

(52) U.S. Cl. CPC H10N 30/8542; H10N 30/093

(57) ABSTRACT

A one-dimensional metal-doped perovskite-type niobate piezoelectric material is disclosed. The one-dimensional metal-doped perovskite-type niobate piezoelectric material has a rod-shape, and is represented by a formula ABO₃, wherein A and B are doped metals, the metal A is one or more selected from the group consisting of Bi, Li, Na, K, Ca, Sr, Ba, Cs and Rb; and the metal B is Nb and one or more selected from the group consisting of Ti, Y, Sc, Zr, Hf, V, Ta, Mn, Fe, Co, Ni, Cu, Al, Zn and Sb. A preparation method and uses of the material, and flexible acoustic sensitive device containing the material and preparation method thereof are disclosed.

### CROSS REFERENCE TO RELATED APPLICATIONS

The application claims the benefit of the Chinese patent application No. 202210262564.7, filed on Mar. 17, 2022, entitled “One-dimensional metal doped perovskite-type niobate piezoelectric material and preparation method thereof”, the Chinese patent application No. 202210270270.9, filed on Mar. 18, 2022, entitled “Preparation method of high-performance piezoelectric acoustic sensor simulating human cochlea outer ear hair cell array”, and the Chinese patent application No. 202210267872.9, filed on Mar. 18, 2022, entitled “Preparation method of high-performance self-powered acoustic sensor based on piezoelectric nanorods”, the contents of which are specifically and entirely incorporated herein by reference.

### FIELD

The present disclosure relates to the technical field of inorganic material preparation, in particular to one-dimensional metal-doped perovskite-type niobate piezoelectric material and a preparation method and a use thereof, a flexible acoustic sensitive device and a preparation method thereof.

### BACKGROUND

With respect to the people suffering from moderate or severe hearing loss due to the damage of cochlear hair cell, the current treatment solution is to receive artificial Cochlear Implants (CI). However, the traditional CI are still uncomfortable for the wearers due to the external devices, large power and low speech recognition capacity, the mismatch between rigid CI electrodes and soft tissue may give rise to nerve damage and tinnitus. To overcome these problems, the flexible self-powered piezoelectric artificial cochlear have attracted the widespread attention. Furthermore, along with the development of the Internet of Things and Artificial Intelligence, the research of self-powered acoustic sensors has also received extensive attention.

The piezoelectric nano-generator is a nano-generator manufactured based on the principle of piezoelectric effect, the piezoelectric material is the core for determining its properties; as compared with isotropic piezoelectric material, the anisotropic piezoelectric material (e.g., nanowire and nanosheet) shows superior properties. In addition, one-dimensional nano-materials are considered as the basic building block of nano-devices applied in the electronic, photovoltaic, electromechanical, sensing and other fields in the future, thus the preparation and research of one-dimensional piezoelectric material are completely indispensable. Given that the ordinary people have imposed more emphasis on environmental protection, the practitioners in the field of piezoelectric ceramic wish to replace the lead zirconate titanate (PZT) ceramic widely used at present with lead-free piezoelectric ceramic. Among them, niobate-based piezoelectric ceramic is the most desired choice to replace the PZT ceramic due to its high temperature ferroelectric piezoelectric property, nonlinear optical property and broad combinations of phase transition and properties. It is reported that the piezoelectric property of the synthesized niobate-based ceramic with orientation is comparable to the ordinary PZT ceramic in commercial use. The current synthesis methods of the one-dimensional ABO₃ type perovskite comprise a solvothermal method, a hydrothermal method, re-precipitation method, sol-gel method and a molten salt method, but the synthesis methods at present cannot achieve the one-dimensional piezoelectric material with precise control of components A and B simultaneously. As the material most desirable to replace the PZT ceramic, niobate also has an important value in the field of piezoelectric devices. Due to the excellent piezoelectric property of one-dimensional piezoelectric material, the pressure sensing devices based on one-dimensional micro/nano-structures (e.g., KNbO₃, NaNbO₃, (Na,K)NbO₃) has strong competitiveness in the electronic application field, and have promising application prospect in the research fields such as sensing, wearable, biochemical, self-powered electric devices and integrated circuits. However, the simple one-dimensional niobate material has vast difference from the multi-element materials in terms of properties, thus it has important significance to develop one-dimensional multicomponent perovskite niobate material in order to improve piezoelectric property and pressure sensitivity of the material.

In addition, for the sake of improving properties of the piezoelectric acoustic sensors, the researchers have tried to prepare different piezoelectric materials with high performance or modify the preparation process of sensors, such as electrospinning method, sol-gel method. However, the development of novel materials, such as high performance piezoelectric polymer, high performance piezoelectric ceramic or new piezoelectric composite material, suffers from the defects of long development cycle and large uncertainty. The new preparation processes (e.g., electrospinning method) are only applicable to solvent soluble polymer based materials. The sol-gel method is generally applicable to the ceramic materials with precursors, but the method has the disadvantages such as complicated steps, consuming a long time, expensive and lacking general applicability.

Therefore, it has been a hotspot of researchers to develop a high-performance piezoelectric acoustic sensor with simple and rapid preparation method and being cost-effective and suitable for various kinds of piezoelectric acoustic sensors.

### SUMMARY

The present disclosure aims to overcome the defects that the piezoelectric property and pressure sensitivity of lead-free piezoelectric material prepared in the prior art are inferior to those of the lead-containing piezoelectric material and that the one-dimensional morphology of perovskite material cannot be obtained in a large scale, and provides one-dimensional metal-doped perovskite niobate piezoelectric material and a preparation method and a use thereof, and a flexible acoustic sensitive device and a preparation method thereof, the piezoelectric material has excellent piezoelectric property and pressure sensitivity. In addition, the piezoelectric material has the advantages such as the preparation process is simple and environmentally friendly, can be easily operated, and the product is controllable. Further, the lead-free piezoelectric material is combined with a polymer material and subjected to the structured design, thereby producing a high-performance piezoelectric acoustic sensor that simulates a human cochlear outer ear hair cell array.

In order to achieve the above objectives, a first aspect of the present disclosure provides one-dimensional metal-doped perovskite niobate piezoelectric material, wherein the one-dimensional metal-doped perovskite niobate piezoelectric material has a rod-shape, and is represented by a formula ABO₃, wherein A and B are doped metals, the metal A is one or more selected from the group consisting of Bi, Li, Na, K, Ca, Sr, Ba, Cs and Rb; and the metal B is Nb and one or more selected from the group consisting of Ti, Y, Sc, Zr, Hf, V, Ta, Mn, Fe, Co, Ni, Cu, Al, Zn and Sb.

A second aspect of the present disclosure provides a method of preparing the one-dimensional metal-doped perovskite niobate piezoelectric material comprising:
1) mixing niobium pentoxide, a first alkali metal salt or an alkaline earth metal salt, and a first molten salt uniformly and subjecting the mixture to a calcination process to obtain one-dimensional non-perovskite-type niobates;
2) contacting the one-dimensional non-perovskite type niobates with an acid and carrying out an ion exchange reaction to obtain the one-dimensional non-perovskite niobates containing hydronium ions;
3) thermally decomposing the one-dimensional non-perovskite niobates to obtain one-dimensional rod-shaped Nb₂O₅;
4) using the one-dimensional rod-shaped Nb₂O₅ as template and blending with a transition metal oxide, a second alkali metal salt or alkaline earth metal salt, and a second molten salt uniformly and subjecting the mixture to a calcination process, to prepare a one-dimensional metal-doped perovskite niobate piezoelectric material.

A third aspect of the present disclosure provides a one-dimensional metal-doped perovskite niobate piezoelectric material produced with the aforementioned method.

A fourth aspect of the present disclosure provides a use of the aforementioned one-dimensional metal-doped perovskite niobate piezoelectric material in an acoustic sensor.

A fifth aspect of the present disclosure provides a use of the one-dimensional metal-doped perovskite niobate piezoelectric material in a piezoelectric acoustic sensor simulating a human cochlear outer ear hair cell array.

A sixth aspect of the present disclosure provides a method of preparing the flexible acoustic sensitive device compring:
(1) formulation of magnetic material ink: mixing a nanoscaled magnetic material and a polymer material uniformly under the action of an organic diluent, to obtain a magnetic material ink useful for printing a magnetic micro-cone array;
(2) printing: directly writing the magnetic material ink on the surface of a piezoelectric acoustic sensor film, to obtain a magnetic ink droplet having a certain pattern distribution, wherein the piezoelectric acoustic sensor film is prepared by using the aforementioned one-dimensional metal-doped perovskite niobate piezoelectric material;
(3) magnetic field induction: placing the printed device in step (2) in a magnetic field and a high-temperature environment to subject to induction and solidification, thereby prepare a flexible acoustic sensitive device with a cone-shaped three-dimensional structure.

A seventh aspect of the present disclosure provides a flexible acoustic sensitive device produced with the aforementioned preparation method.

An eighth aspect of the present disclosure provides a method of preparing the flexible acoustic sensitive device compring:
(1) mixing rod-shaped piezoelectric material with a polymer uniformly, to obtain a mixed ink that can be used for spin coating or blade coating and is composed of piezoelectric nanorods and a polymer; wherein the rod-shaped piezoelectric material is the aforementioned one-dimensional metal-doped perovskite nanorod piezoelectric material;
(2) preparing a cured piezoelectric layer through spin coating or blade coating; placing the cured piezoelectric layer in a high pressure DC voltage and high temperature environment and subjecting to polarization;
(3) preparing a patterned electrode on a surface of the polarized piezoelectric layer by using an electrode ink and the printing, vacuum evaporation and silk-screen printing process according to sensor requirement; extending the electrode outward with a conductive filament to prepare a flexible acoustic sensitive device.

A ninth aspect of the present disclosure provides a flexible acoustic sensitive device produced with the aforementioned preparation method.

The present disclosure has the following advantages over the prior art:
1) the present disclosure uses structural similarities of materials, and produce a large number of one-dimensional morphology metal-doped perovskite thin dielectric material through mild evolution of a portion of structure under the molten salt conditions;
2) the one-dimensional morphology metal-doped perovskite piezoelectric material of the present disclosure has the advantages that the preparation process is environmentally friendly, simple and can be easily operated, and the product is controllable, thereby providing a powerful pathway for the production of one-dimensional multi-element perovskite in the fields associated with electronics, piezoelectricity and energy.

### BRIEF DESCRIPTION OF THE DRAWINGS

FIG. 1 is a schematic flow diagram of a preparation method of the one-dimensional metal-doped perovskite niobate piezoelectric material of the present disclosure;

FIG. 2 illustrates an X-Ray Diffraction (XRD) spectrogram of a non-perovskite type niobate prepared according to an intermediate process of Example 1 of the present disclosure;

FIG. 3 illustrates an XRD spectrogram of the one-dimensional metal-doped perovskite niobate piezoelectric material prepared in Example 1 of the present disclosure;

FIG. 4 shows a Scanning Electron Microscope (SEM) image of the one-dimensional metal-doped perovskite niobate piezoelectric material prepared in Example 1 of the present disclosure;

FIG. 5 shows a Transmission Electron Microscope (TEM) image of the one-dimensional metal-doped perovskite niobate piezoelectric material prepared in Example 1 of the present disclosure;

FIG. 6 illustrates a High Resolution Transmission Electron Microscope (HRTEM) image and a selected-area electron diffraction pattern of the one-dimensional metal-doped perovskite niobate piezoelectric material prepared in Example 1 of the present disclosure;

FIG. 7 shows a schematic diagram of a method of the present disclosure;

FIG. 8 shows an electron microscope diagram of a cone-shaped array of the present disclosure;

FIG. 9 illustrates an output voltage graph of a piezoelectric acoustic sensor film device in the present disclosure;

FIG. 10 shows an output voltage distribution diagram of a piezoelectric acoustic sensor film device in the present disclosure at different angles;

FIG. 11 illustrates an output voltage graph showing a piezoelectric acoustic sensor film device of the present disclosure for recording a voice dialog.

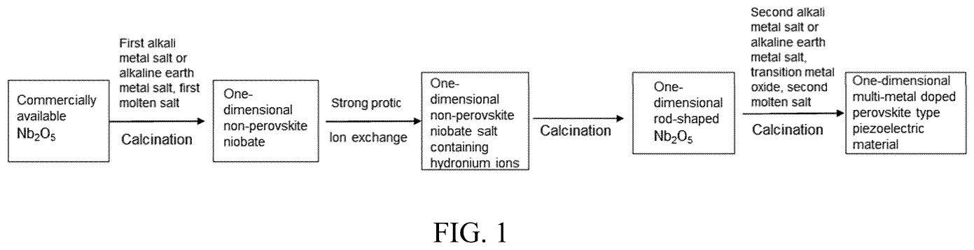

### DETAILED DESCRIPTION

The terminals and any value of the ranges disclosed herein are not limited to the precise ranges or values, such ranges or values shall be comprehended as comprising the values adjacent to the ranges or values. As for numerical ranges, the endpoint values of the various ranges, the endpoint values and the individual point value of the various ranges, and the individual point values may be combined with one another to produce one or more new numerical ranges, which should be deemed have been specifically disclosed herein.

As previously mentioned, a first aspect of the present disclosure provides one-dimensional metal-doped perovskite niobate piezoelectric material, wherein the one-dimensional metal-doped perovskite niobate piezoelectric material has a rod-shape, and is represented by a formula ABO₃, wherein A and B are doped metals, the metal A is one or more selected from the group consisting of Bi, Li, Na, K, Ca, Sr, Ba, Cs and Rb; and the metal B is Nb and one or more selected from the group consisting of Ti, Y, Sc, Zr, Hf, V, Ta, Mn, Fe, Co, Ni, Cu, Al, Zn and Sb.

According to the present disclosure, the metal A is preferably one or more selected from the group consisting of Li, Na, K, Ca, Sr, Ba, Cs and Rb; more preferably, the metal A is one or more selected from the group consisting of Li, Na and K.

According to the present disclosure, the metal B is preferably Nb and one or more selected from the group consisting of Ti, Y (yttrium), Sc (scandium), Zr (zirconium), Hf (hafnium), V (vanadium), Ta (tantalum), Mn, Fe, Co, Ni, Cu, Al and Sb; more preferably, the metal B is selected from Nb and Ta and/or Sb.

According to the present disclosure, a molar ratio of the total molar amount of the metal A, the total molar amount of the metal B to the total molar amount of the piezoelectric materials is (1-2): (1-2): 1, preferably 1:1:1, based on the total molar amount of the one-dimensional metal-doped perovskite ferroelectric piezoelectric materials.

According to the present disclosure, the one-dimensional metal-doped perovskite niobate piezoelectric materials have an average length of 0.1-1,000 μm, preferably an average length of 0.1-50 μm; and an average diameter of 10-5,000 nm, preferably an average diameter of 100-2,000 nm.

The present disclosure provides a one-dimensional topography metal-doped perovskite niobate piezoelectric material, which can improves the piezoelectric properties of the piezoelectric material and the perception of weak mechanical signals.

A second aspect of the present disclosure provides a method of preparing the one-dimensional metal-doped perovskite niobate piezoelectric material compring:
1) mixing niobium pentoxide, a first alkali metal salt or an alkaline earth metal salt, and a first molten salt uniformly and subjecting the mixture to a calcination process to obtain one-dimensional non-perovskite type niobates;
2) contacting the one-dimensional non-perovskite type niobate with an acid and carrying out an ion exchange reaction to obtain a one-dimensional non-perovskite niobate containing hydronium ions;
3) thermally decomposing the one-dimensional non-perovskite niobate to obtain one-dimensional rod-shaped Nb₂O₅;
4) using the one-dimensional rod-shaped Nb₂O₅ as template and blending with a transition metal oxide, a second alkali metal salt or alkaline earth metal salt and a second molten salt uniformly, and subjecting the mixture to a calcination process, to prepare one-dimensional metal-doped perovskite niobate piezoelectric material.

According to the present disclosure, a molar ratio of the used amount of the niobium pentoxide, the first alkali metal salt or alkaline earth metal salt to the amount of the first molten salt in step 1) is 1: (0.01-0.8): (1-100); preferably, a molar ratio of the used amount of the niobium pentoxide, the first alkali metal salt or an alkaline earth metal salt to the first molten salt is 1: (0.01-0.8): (1-80); more preferably, a molar ratio of the used amount of the niobium pentoxide, the first alkali metal salt or an alkaline earth metal salt to the first molten salt is 1: (0.01-0.5): (1-50).

According to the present disclosure, the acid in step 2) is hydrochloric acid, nitric acid or sulphuric acid; the acid is preferably nitric acid.

According to the present disclosure, the acid has a concentration of 0-10 mol/L, and is not zero.

According to the present disclosure, the temperature of the ion exchange reaction in step 2) is within a range of 30-200° C., and the time is not less than 0.1 h; preferably, the temperature is within a range of 90-150° C., and the time is within a range of 0.5-72 h

According to the present disclosure, the feeding ratio of the non-perovskite niobate to the acid in step 2) is 1 g: (1-2,000 mL); preferably 1 g: (10-500 mL).

According to the present disclosure, the thermal decomposition temperature in step 3) is within a range of 200-1,000° C.; the time is not less than 10 min; preferably, the thermal decomposition temperature is within a range of 400-650° C., the time is within a range of 30-180 min.

According to the present disclosure, a molar ratio of the used amount of the one-dimensional rod-shaped Nb₂O₅, the transition metal oxide, the second alkali metal salt or alkaline earth metal salt, and the second molten salt in step 4) is 1: (0-0.5): (0.1-50): (1-200); preferably, a molar ratio of the used amount of the one-dimensional rod-shaped Nb₂O₅, the transition metal oxide, the second alkali metal salt or alkaline earth metal salt, and the second molten salt in step 4) is 1: (0-0.5): (0.1-25): (1-100); more preferably, a molar ratio of the used amount of the one-dimensional rod-shaped Nb₂O₅, the transition metal oxide, the second alkali metal salt or alkaline earth metal salt, and the second molten salt in step 4) is 1: (0-0.2): (0.1-25): (1-100).

According to the present disclosure, the first alkali metal salt in step 1) is the same as or different from the second alkali metal salt in step 4).

According to the present disclosure, the alkaline earth metal salt in step 1) is the same as or different from the alkaline earth metal salt in step 4).

According to the present disclosure, the first alkali metal salt or alkaline earth metal salt in step 1) and the second alkali metal salt or alkaline earth metal salt in step 4) are each independently one or more selected from the group consisting of Li₂CO₃, Na₂CO₃, K₂CO₃, CaCO₃, SrCO₃, BaCO₃, LiNO₃, NaNO₃, KNO₃, Ca(NO₃)₂, Sr(NO₃)₂ and Ba(NO₃)₂.

According to the present disclosure, it is preferred that the first alkali metal salt or alkaline earth metal salt in step 1) and the second alkali metal salt or alkaline earth metal salt in step 4) are each independently one or more selected from the group consisting of Li₂CO₃, Na₂CO₃, K₂CO₃, CaCO₃, SrCO₃ and BaCO₃.

According to the present disclosure, the transition metal oxide in step 4) is one or more selected from the group consisting of TiO₂, Y₂O₃, Sc₂O₃, ZrO₂, HfO₂, V₂O₅, Ta₂O₅, MnO₂, Fe₂O₃, CoO₂, NiO, Ni(OH)₂, CuO₂, Al₂O₃, ZnO, Sb₂O₃, Sb₂O₅ and Bi₂O₃.

According to the present disclosure, it is preferred that the transition metal oxide is one or more selected from the group consisting of TiO₂, Y₂O₃, Sc₂O₃, ZrO₂, HfO₂, V₂O₅, Ta₂O₅, MnO₂, Fe₂O₃, CoO₂, NiO, Ni(OH)₂, CuO₂, Al₂O₃, ZnO and Sb₂O₃.

According to the present disclosure, the first molten salt in step 1) is the same as or different from the second molten salt in step 4).

According to the present disclosure, the first molten salt in step 1) and the second molten salt in step 4) are each independently selected from a halide and/or nitrate.

In accordance with the present disclosure, the halide comprises one or more selected from the group consisting of sodium chloride, potassium chloride, cesium chloride, rubidium chloride, sodium bromide, potassium bromide, cesium bromide and rubidium bromide. Preferably, the halide comprises one or more selected from the group consisting of sodium chloride, potassium chloride, cesium chloride and rubidium chloride.

The nitrate salt comprises one or more selected from the group consisting of cesium nitrate, sodium nitrate, potassium nitrate and calcium nitrate; preferably, the nitrate salt comprises one or more selected from the group consisting of sodium nitrate, potassium nitrate and calcium nitrate.

According to the present disclosure, the mixing conditions in step 1) are the same as or different from the mixing conditions in step 4); the mixing comprises mechanical mixing means such as ball-milling and grinding, and/or lubrication by means of liquid medium. The liquid medium may be a conventional organic or inorganic liquid, such as water, ethanol, methanol and acetone.

According to the present disclosure, the calcination conditions in step 1) are the same as or different from the calcination conditions in step 4).

According to the present disclosure, the mixing conditions in step 1) are the same as or different from those in step 4), the mixing conditions comprise a temperature of 0-100° C.

According to the present disclosure, the calcination temperature in steps 1) and 4) is within a range of 200-1,200° C., the time is within the range of 1 min and 20 h; preferably, the calcination temperature in steps 1) and 4) is within a range of 300-1,000° C., the time is within the range of 10 min and 10 h.

The preparation method of the one-dimensional metal-doped perovskite niobate piezoelectric material according to the present disclosure further comprises: washing and treating the mixed and calcined product of step 1), and further comprises washing and treating the mixed and calcined product of step 4) to remove the molten salt therein.

The washing is not specifically limited in the present disclosure, for example, washing the product by using deionized water for several times until there is no molten salt anion, preferably using hot deionized water, wherein the temperature of the hot deionized water is within a temperature range of 30-100° C.

Further, the washed product in the present disclosure may be further subjected to a drying treatment, wherein the conditions of drying treatment may be within a range of 50-300° C., preferably 50-150° C.

A third aspect of the present disclosure provides one-dimensional metal-doped perovskite niobate piezoelectric material produced with the aforementioned preparation method.

A fourth aspect of the present disclosure provides a use of the aforementioned one-dimensional metal-doped perovskite niobate piezoelectric material in an acoustic sensor.

A fifth aspect of the present disclosure provides a use of the aforementioned one-dimensional metal-doped perovskite niobate piezoelectric material in a piezoelectric acoustic sensor simulating a human cochlear outer ear hair cell array.

A sixth aspect of the present disclosure provides a method of preparing the flexible acoustic sensitive device compring:
(1) formulation of magnetic material ink: mixing a nanoscaled magnetic material and a polymer material uniformly under the action of an organic diluent, to obtain a magnetic material ink useful for printing a magnetic micro-cone array;
(2) printing: directly writing the magnetic material ink on the surface of a piezoelectric acoustic sensor film, to obtain a magnetic ink droplet having a certain pattern distribution, wherein the piezoelectric acoustic sensor film is prepared by using the aforementioned one-dimensional metal-doped perovskite niobate piezoelectric material;
(3) magnetic field induction: placing the printed device in step (2) in a magnetic field and a high-temperature environment to subject to induction and solidification, thereby prepare a flexible acoustic sensitive device with a cone-shaped three-dimensional structure.

According to the present disclosure, the organic diluent is one or more selected from the group consisting of alkanes, alcohols, ketones and amides.

According to the present disclosure, the nanoscaled magnetic material is at least one of an iron cobalt nickel oxide having a magnetic property and a solid solution thereof.

According to the present disclosure, the polymer material in step (1) is a curable prepolymer, including but not limited to one or more selected from the group consisting of a silicone rubber prepolymer, a self-crosslinking type polyacrylate prepolymer and a self-crosslinking type epoxy resin prepolymer.

According to the present disclosure, the content of nanoscaled magnetic material is 0-80 wt %, and is not zero, based on the total weight of the ink.

According to the present disclosure, the conditions of direct writing comprise: an air pressure for printing is within a range of 1-70 psi, a printing speed is within a range of 0.01-50 mm/s; the magnetic ink droplet has a diameter of 50-5,000 μm.

According to the present disclosure, a magnetic field strength in step (3) is within a range of 0-15 KGs and is not 0.

According to the present disclosure, the curing conditions in step (3) comprise: a temperature within a range of 30-150° C., and a curing time not less than 5 minutes.

According to the present disclosure, the method of preparing the piezoelectric acoustic sensor film compring:
blending the aforementioned one-dimensional metal-doped perovskite niobate piezoelectric material with a polymer uniformly, to obtain a mixed ink that can be used for spin coating or blade coating and is composed of the one-dimensional metal-doped perovskite niobate piezoelectric material and the polymer material; a piezoelectric layer having a certain thickness is produced through spin coating, vapor deposition or blade coating; a conductive layer is disposed on a surface of the piezoelectric layer through spin coating, vapor deposition or blade coating, another surface of the piezoelectric layer is used for subsequent magnetic array printing;
wherein the polymer material is selected from curable prepolymers, including but not limited to one or more selected from the group consisting of silicone rubber prepolymer, self-crosslinking type polyacrylate prepolymer and self-crosslinking type epoxy resin prepolymer;
the content of one-dimensional metal-doped perovskite niobate piezoelectric material is 0-80 wt %, and is not zero, based on the total weight of the ink.

A seventh aspect of the present disclosure provides a flexible acoustic sensitive device produced with the aforementioned preparation method.

According to the present disclosure, the flexible acoustic sensitive device comprises a piezoelectric acoustic sensor stimulating a human cochlear outer ear hair cell array.

An eighth aspect of the present disclosure provides a method of preparing the flexible acoustic sensitive device compring:
(1) mixing rod-shaped piezoelectric materials with a polymer uniformly, to obtain a mixed ink that can be used for spin coating or blade coating and is composed of piezoelectric nanorods and a polymer; wherein the rod-shaped piezoelectric materials is the aforementioned one-dimensional metal-doped perovskite nanorod piezoelectric material;
(2) preparing a cured piezoelectric layer through spin coating or blade coating; placing the cured piezoelectric layer in a high pressure DC voltage and high temperature environment and subjecting to polarization;
(3) preparing a patterned electrode on a surface of the polarized piezoelectric layer by using an electrode ink and the printing, vacuum evaporation and silk-screen printing process according to sensor requirement; extending the electrode outward with a conductive filament to prepare a flexible acoustic sensitive device.

A ninth aspect of the present disclosure provides a flexible acoustic sensitive device produced with the aforementioned preparation method.

According to the present disclosure, the flexible acoustic sensitive device comprises a piezoelectric acoustic sensor film.

The present disclosure will be described in detail below with reference to examples.

In the following Examples and Comparative Examples, the structure of the sample was characterized by X-ray powder diffraction (XRD, Rigaku D/Max 2500) method; the microstructure of the sample was observed by using a field emission scanning electron microscope (SEM, JSM-7500); the microstructure of the sample and selected area electron diffraction were observed by using a transmission electron microscope (TEM, JEM-F200).

Piezoelectric performance test: the piezoelectric coefficient d₃₃ of a sample was measured with a quasi-static d₃₃/d₃₁ meter (ZJ-6A type, manufactured by the Institute of Acoustics, Chinese Academy of Sciences).

Stress sensitivity test: the electrical signals were acquired with the digital source meter having a Model 6514 manufactured by the Keithley Corporation of the USA and the interactive source meter having a model MR8875-30 manufactured by the HIOKI Company in the Japan.

All the raw materials were commercially available from the Sigma Aldrich, the Inno Chem, and the Beijing Chemical Reagent Co., Ltd., in China.

### Example 1

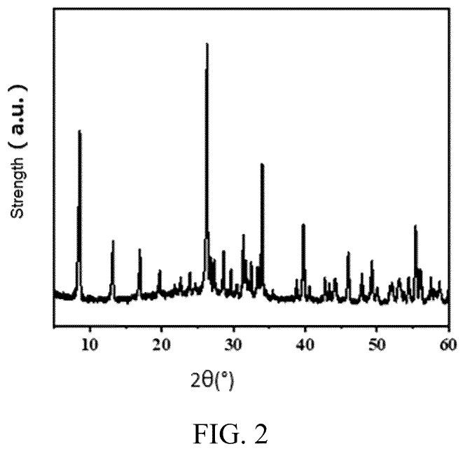

(1) mixing materials: Nb₂O₅, K₂CO₃ and KCl were milled and mixed in water in a molar ratio of 1:0.3:10, then subjected to drying at a temperature of 80° C. and transferred the dried materials to a crucible; calcination treatment: the mixed materials were calcined at 780° C. for 3 h;
dissolution: the heat-treated sample was lump-shaped, put in distilled water and boiled and stirred with a glass rod until the molten salt was dissolved, the lumps were crushed;
washing and drying: the sample was repeatedly rinsed with distilled water at 30° C. for several times until Cl⁻ ions were not be detected by the reagent AgNO₃, the sample was dried in an oven at 120° C. and subjected to heat preservation for 3 h, a one-dimensional non-perovskite type niobate (i.e., white rod-shaped KNb₃O₈ powder) was obtained; FIG. 2 illustrated an XRD spectrogram of a non-perovskite type niobate prepared in Example 1 of the present disclosure; as can be seen from FIG. 2, a pure non-perovskite type KNb₃O₈ was obtained;
(2) ion exchange: 1 g of the KNb₃O₈ was blended with 400 mL of HNO₃ solution with a concentration of 2 mol/L and stirred at 140° C. for 48 h; the solution was filtered, the sample was repeatedly scrubbed with distilled water, and subjected to drying at 80° C. for 4 h, a white rod-shaped H₃ONb₃O₈ powder was obtained;
(3) thermal decomposition: the H₃ONb₃O₈ powder was calcined at 550° C. for 1 h, a white rod-shaped Nb₂O₅ powder was obtained;
(4) blending materials: the rod-shaped Nb₂O₅ powder, Ta₂O₅, Sb₂O₃, K₂CO₃, Na₂CO₃, Li₂CO₃ and KCl were subjected to ball-milling and blending in a molar ratio 0.86:0.1:0.04:0.4:0.56:0.04:10 in acetone, then subjected to drying at a temperature of 80° C. and transferring the dried materials to a crucible;
calcination: calcination was performed at 900° C. for 2.5 h;
dissolution: the heat-treated sample was lump-shaped, put in distilled water and boiled and stirred with a glass rod until the molten salt was dissolved, the lumps were crushed;
washing and drying: the sample was repeatedly rinsed with hot distilled water for several times until Cl⁻ ions were not be detected by the reagent AgNO₃, the sample was dried in an oven at 150° C. and subjected to t preservation for 3 h, the white rod-shaped (Li,Na,K) (Nb,Ta,Sb) O₃ powder was obtained.

The rod-shaped (Li,Na,K) (Nb, Ta, Sb) O₃ powder was tested, the test results showed that the peak position values of the peaks around 22°, 32°, 39°, 46°, 52° and 57° were similar with the characteristic peaks of sodium niobate (JCPDS 73-882), potassium niobate (JCPDS 71-946); by comparison, the pure perovskite type orthogonal phase (Li,Na,K) (Nb,Ta,Sb) O₃ was prepared in Example 1 of the present disclosure.

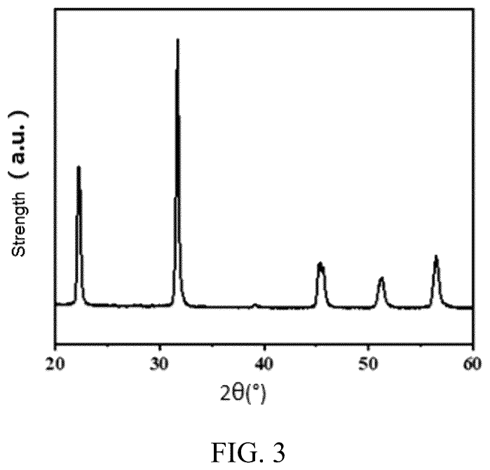

In addition, FIG. 3 illustrated an XRD spectrogram of the one-dimensional metal-doped perovskite niobate piezoelectric material prepared in Example 1 of the present disclosure; as shown in FIG. 3, the pure perovskite type (Li,Na,K) (Nb,Ta,Sb) O₃ was obtained.

FIG. 4 illustrated a SEM image of the one-dimensional metal-doped perovskite niobate piezoelectric material prepared in Example 1 of the present disclosure. As can be seen from FIG. 4, the obtained metal-doped perovskite piezoelectric material had a rod-shaped morphology.

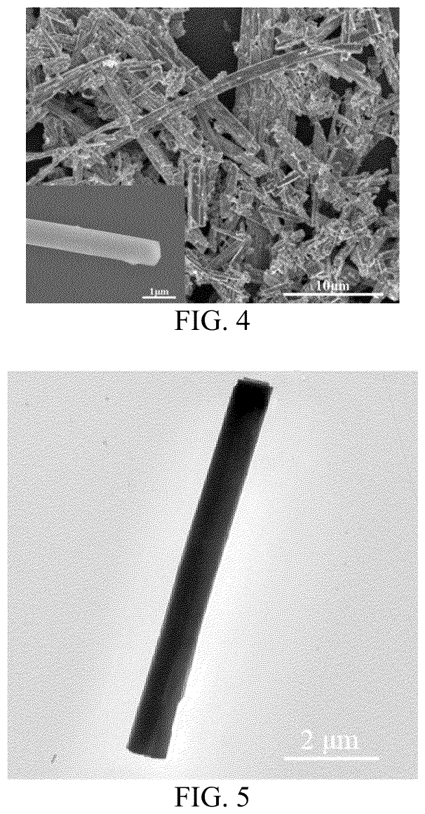

FIG. 5 illustrated a TEM image of the one-dimensional metal-doped perovskite niobate piezoelectric material prepared in Example 1 of the present disclosure. As can be seen from FIG. 5, the obtained metal-doped perovskite piezoelectric material had a rod-shaped morphology.

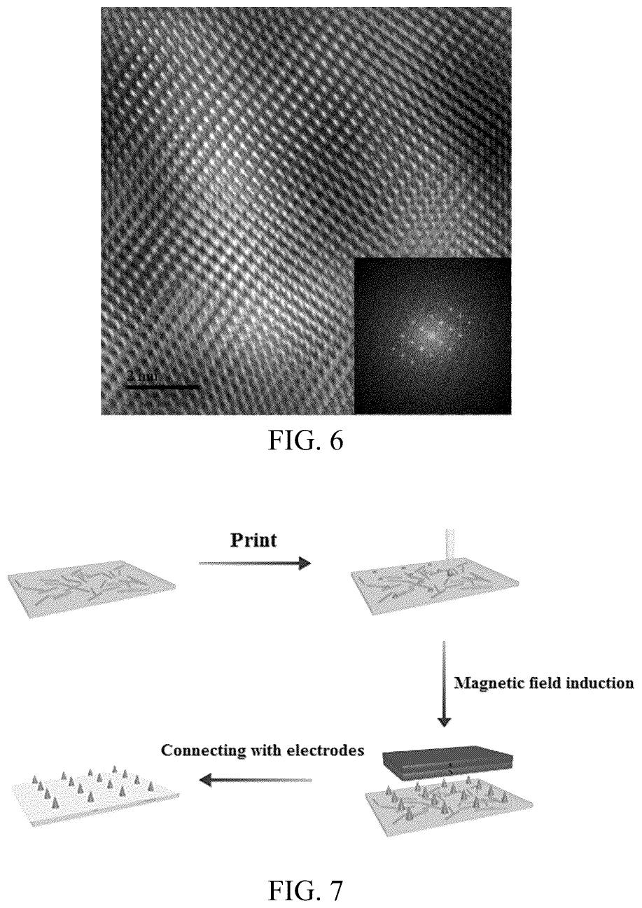

FIG. 6 illustrated a HRTEM image and a selected-area electron diffraction pattern of the one-dimensional metal-doped perovskite niobate piezoelectric material prepared in Example 1 of the present disclosure; as shown by FIG. 6, the obtained metal-doped perovskite niobate piezoelectric material was a crystalline material.

### Example 2

(1) mixing materials: Nb₂O₅ and KCl were mixed in a certain molar ratio, namely Nb₂O₅: KCl=1:15, and ball-milled in ethanol, then subjected to drying at a temperature of 80° C. and transferred the dried materials to a crucible;
heat treatment: calcination was performed at 800° C. for 3 h;
dissolution: the heat-treated sample was lump-shaped, put in distilled water and boiled and stirred with a glass rod until the molten salt was dissolved, the lumps were crushed;
washing and drying: the sample was repeatedly rinsed with distilled water at 50° C. for several times until Cl⁻ ions were not be detected by the reagent AgNO₃, the sample was dried in an oven at 120° C. and subjected to heat preservation for 3 h, a white rod-shaped KNb₃O₈ powder was obtained;
(2) ion exchange: 1 g of the KNb₃O₈ was blended with 400 mL of HNO₃ solution with a concentration of 4 mol/L and stirred at 120° C. for 48 h; the solution was filtered, the sample was repeatedly scrubbed with distilled water, and subjected to drying at 80° C. for 4 h, a white rod-shaped H₃ONb₃O₈ powder was obtained;
(3) thermal decomposition: the H₃ONb₃O₈ powder was calcined at 600° C. for 1 h, a white rod-shaped Nb₂O₅ powder was obtained;
(4) blending materials: the rod-shaped Nb₂O₅ powder, Sb₂O₃, K₂CO₃, Na₂CO₃, Li₂CO₃ and KCl were subjected to ball-milling and blending according to a molar ratio of 0.96:0.04:0.48:0.48:0.04:10 in ethanol, then subjected to drying at a temperature of 80° C. and transferring the dried materials to a crucible;
calcination: calcination was performed at 850° C. for 3 h;
dissolution: the heat-treated sample was lump-shaped, put in distilled water and boiled and stirred with a glass rod until the molten salt was dissolved, the lumps were crushed;
washing and drying: the sample was repeatedly rinsed with hot distilled water for several times until the Cl⁻ ions were not be detected by the reagent AgNO₃, the sample was dried in an oven at 120° C. and subjected to heat preservation for 3 h, the white rod-shaped (Li,Na,K) (Nb,Sb) O₃ powder was obtained.
Example 3

(1) mixing materials: Nb₂O₅, K₂CO₃ and KCl were mixed in a certain molar ratio, namely Nb₂O₅: K₂CO₃: KCl=1:1: 10, and ball-milled in ethanol, then subjected to drying at a temperature of 80° C. and transferred the dried materials to a crucible;
heat treatment: calcination was performed at 800° C. for 3 h;
dissolution: the heat-treated sample was lump-shaped, put in distilled water and boiled and stirred with a glass rod until the molten salt was dissolved, the lumps were crushed;
washing and drying: the sample was repeatedly rinsed with distilled water at 90° C. for several times until Cl⁻ ions were not be detected by the reagent AgNO₃, the sample was dried in an oven at 120° C. and subjected to heat preservation for 3 h, a white rod-shaped KNb₃O₈ powder was obtained;
(2) ion exchange: 1 g of the KNb₃O₈ was blended with 400 mL of HNO₃ solution with a concentration of 1 mol/L and stirred at 130° C. for 72 h; the solution was filtered, the sample was repeatedly scrubbed with distilled water, and subjected to drying at 80° C. for 4 h, a white rod-shaped H₃ONb₃O₈ powder was obtained;
(3) thermal decomposition: the H₃ONb₃O₈ powder was calcined at 400° C. for 2 h, a white rod-shaped Nb₂O₅ powder was obtained;
(4) blending materials: the rod-shaped Nb₂O₅ powder, Sb₂O₃, K₂CO₃, Na₂CO₃ and KCl were subjected to ball-milling and blending according to a molar ratio of 0.96:0.04:0.5:0.5:10 in ethanol, then subjected to drying at a temperature of 80° C. and transferring the dried materials to a crucible;
calcination: calcination was performed at 800° C. for 3 h;
dissolution: the heat-treated sample was lump-shaped, put in distilled water and boiled and stirred with a glass rod until the molten salt was dissolved, the lumps were crushed;
washing and drying: the sample was repeatedly rinsed with hot distilled water for several times until Cl⁻ ions were not be detected by the reagent AgNO₃, the sample was dried in an oven at 120° C. and subjected to heat preservation for 3 h, the white rod-shaped (Na,K) (Nb,Sb) O₃ powder was obtained.

### Example 4

The example served to describe the flexible acoustic sensitive device (i.e., the high-performance piezoelectric acoustic sensor stimulating a human cochlear outer ear hair cell array) prepared using the method of the present disclosure. As shown in FIG. 7, it showed a schematic diagram of a method of the present disclosure.
(1) formulation of magnetic material ink: a nanoscaled magnetic material iron cobalt nickel oxide and a polymer material (specifically PDMS) were mixed uniformly under the action of an organic diluent (specifically n-hexane), an ink useful for printing a magnetic micro-cone array was obtained; wherein the content of the nanoscaled magnetic material was 50%, based on total weight of the ink;
(2) printing: the magnetic material ink was directly written on the surface of a piezoelectric acoustic sensor film, to obtain a magnetic ink droplet having a certain pattern distribution, wherein an air pressure for directing writing and printing was 10 psi, the printing speed was 2 mm/s, a diameter of the magnetic ink droplet was 400 μm;
(3) magnetic field induction: the printed device in step (2) was placed in a magnetic field and a high-temperature environment to subject to induction and solidification, wherein the magnetic field strength was 1 KGs; the curing temperature was 80° C. and the curing time was 120 min; a flexible acoustic sensitive device with a cone-shaped three-dimensional structure was obtained.

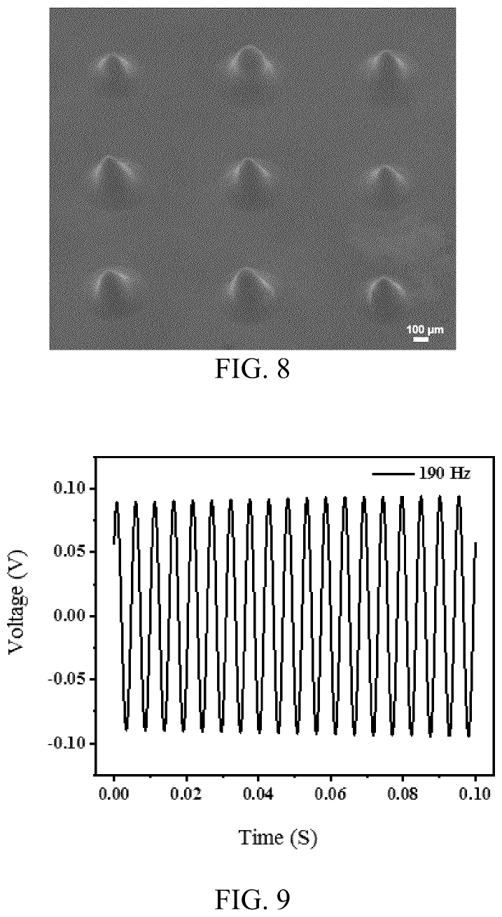

FIG. 8 showed an electron microscope diagram of a cone-shaped array of the present disclosure; as can be seen from FIG. 8, the point density of cone array was 3numbers/mm², an interval between two adjacent points was 600 μm, a single cone had a half height width of 90 μm, the cone array had a height of 130 μm.

### Example 5

The Example served to describe a flexible acoustic sensitive device (i.e., a piezoelectric acoustic sensor film) prepared using the method of the present disclosure.
(1) the rod-shape piezoelectric materials prepared in Example 1 was mixed uniformly with a polymer (specifically PDMS), to obtain a mixed ink that can be used for spin coating or blade coating and is composed of piezoelectric nanorods and a polymer;
(2) a cured piezoelectric layer was prepared through spin coating or blade coating; the curing conditions were selected according to the characteristics of the polymer material to obtain the cured piezoelectric layer; and the cured piezoelectric layer was placed in a high pressure DC voltage and high temperature environment and subjecting to polarization;
(3) a patterned electrode on a surface of the polarized piezoelectric layer was prepared by using an electrode ink and the printing, vacuum evaporation and silk-screen printing process according to sensor requirement; the electrodes were extended outward with a conductive filament, a flexible acoustic sensitive device was prepared.

FIG. 9 illustrated an output voltage graph of a piezoelectric acoustic sensor film device in the present disclosure; as can be seen from FIG. 9, the audio file with a fixed frequency of 190 Hz was played in the condition of 90 dB, the distance between the sensor and the audio source was 2 cm, the output voltage of the sensor was 95 mV.

FIG. 10 showed an output voltage distribution diagram of a piezoelectric acoustic sensor film device in the present disclosure at different angles; as can be seen from FIG. 10, the voltage reached the minimum at the angles 0° and 180°, and reached the maximum at the angle 90°. The various angles corresponded to different output voltage signals, which demonstrated the angle dependence of the prepared device. Furthermore, the performance of the device with a micro-cone array is much higher than the rod-shape piezoelectric material based sensor without a micro-cone array.

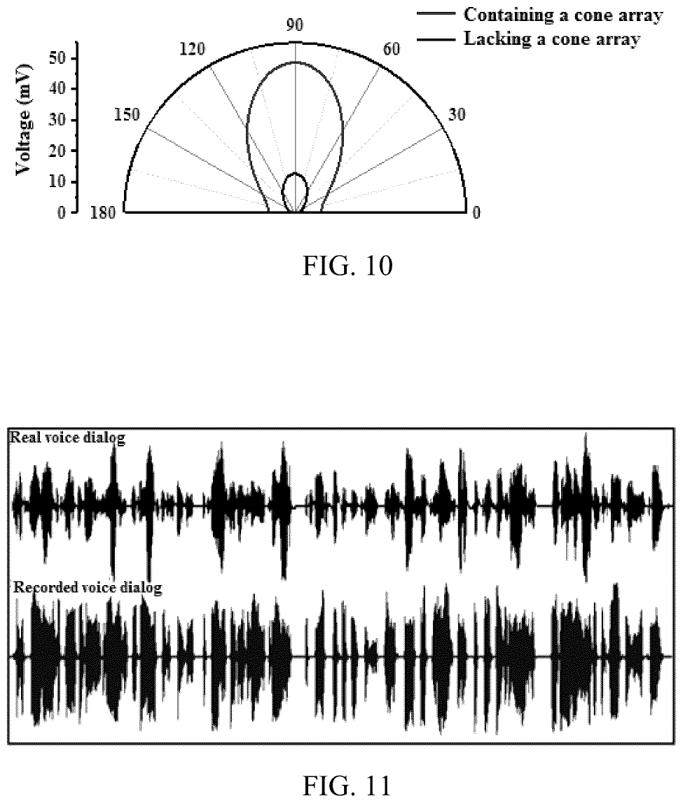

FIG. 11 illustrated an output voltage graph showing a piezoelectric acoustic sensor film device of the present disclosure for recording a voice dialog; as can be seen from FIG. 11, the electrical signals collected by the sensor were almost identical with the original signals of the audio, indicating that the high-performance piezoelectric acoustic sensor can be used for recording the voice message.

### Comparative Example 1

The one-dimensional metal-doped perovskite niobate piezoelectric material was prepared according to the same method as in Example 1, except that Nb₂O₅, K₂CO₃ and KCl were mixed in a molar ratio of 1:1: 10.

The (Li,Na,K) (Nb,Ta,Sb) O₃ powder having a microtopography of sheet was prepared.

### Comparative Example 2

The one-dimensional metal-doped perovskite niobate piezoelectric material was prepared according to the same method as in Example 1, except that H₃ONb₃O₈ was thermally decomposed at 150° C.

The (Li,Na,K) (Nb,Ta,Sb) O₃ powder with an impure perovskite phase was prepared.

### Comparative Example 3

The flexible acoustic sensitive device (i.e., the high-performance piezoelectric acoustic sensor simulating human cochlear outer ear hair cell array) was prepared according to the same method as in Example 4. Except that the content of a nanoscaled magnetic material was 90 wt %.

Given that the ink cannot be used for printing, a flexible acoustic sensitive device lacking a cone-shaped array on its surface was prepared.

### Test Example 1

The properties of the one-dimensional metal-doped perovskite niobate piezoelectric materials prepared in the Examples and Comparative Examples were shown in Table 1.

TABLE 1

| | | Average | Average | Piezoelectric | | |
|---|---|---|---|---|---|---|
| | | length | diameter | property | Sensitivity | |
| Items | Shape | (μm) | (nm) | (pC/N) | (mV/Pa) | |
| Example 1 | rod-shape | 8.2 | 869 | — | — | |
| Example 2 | rod-shape | 11.2 | 732 | — | — | |
| Example 3 | rod-shape | 9.1 | 698 | — | — | |
| Example 4 | flexible acoustic | — | — | 52 | 150.63 | mV/Pa |
| | sensitive device | | | | | |
| Example 5 | flexible acoustic | — | — | 42 | 64.5 | mV/Pa |
| | sensitive device | | | | | |
| Comparative | sheet-shape | 1.5 | 900 | — | — | |
| Example 1 | | | | | | |
| Comparative | rod-shape | 12.1 | 587 | — | — | |
| Example 2 | | | | | | |
| Comparative | flexible acoustic | — | — | 46 | 60 | mV/Pa |
| Example 3 | sensitive device | | | | | |

Note:
The flexible acoustic sensitive device in Example 4 refers to a high-performance piezoelectric acoustic sensor simulating a human cochlear outer ear hair cell array.
The flexible acoustic sensitive device in Example 5 refers to as a piezoelectric acoustic sensor film.

As can be seen from Table 1, both the molar ratio between the raw materials and the content of magnetic material in the ink are crucial for the properties of product and device.

The above content describes in detail the preferred embodiments of the present disclosure, but the present disclosure is not limited thereto. A variety of simple modifications can be made in regard to the technical solutions of the present disclosure within the scope of the technical concept of the present disclosure, including a combination of individual technical features in any other suitable manner, such simple modifications and combinations thereof shall also be regarded as the content disclosed by the present disclosure, each of them falls into the protection scope of the present disclosure.

1-22. (canceled)

23. A one-dimensional metal-doped perovskite-type niobate piezoelectric material, wherein the one-dimensional metal-doped perovskite-type niobate piezoelectric material has a rod-shape, and is represented by a formula ABO₃, wherein A and B are doped metals, the metal A is one or more selected from the group consisting of Bi, Li, Na, K, Ca, Sr, Ba, Cs and Rb; and the metal B is Nb and one or more selected from the group consisting of Ti, Y, Sc, Zr, Hf, V, Ta, Mn, Fe, Co, Ni, Cu, Al, Zn and Sb.

24. The one-dimensional metal-doped perovskite-type niobate piezoelectric material of claim 23, wherein the metal A is one or more selected from the group consisting of Li, Na, K, Ca, Sr, Ba, Cs and Rb;
and/or, the metal B is Nb and one or more selected from the group consisting Ta and Sb.

25. The one-dimensional metal-doped perovskite-type niobate piezoelectric material of claim 23, wherein a molar ratio of the total molar amount of the metal A, the total molar amount of the metal B to the total molar amount of the piezoelectric material is (1-2): (1-2): 1, based on the total molar amount of the one-dimensional metal-doped perovskite ferroelectric piezoelectric material;
and/or, the one-dimensional metal-doped perovskite-type niobate piezoelectric material has an average length of 0.1-1,000 μm and an average diameter of 10-5,000 nm.

26. The one-dimensional metal-doped perovskite-type niobate piezoelectric material of claim 23, wherein a method of preparing the one-dimensional metal-doped perovskite-type niobate piezoelectric material comprising:
1) mixing niobium pentoxide, a first alkali metal salt or an alkaline earth metal salt and a first molten salt uniformly, and subjecting the mixture to a calcination process to obtain a one-dimensional non-perovskite-type niobate;
2) contacting the one-dimensional non-perovskite-type niobate with an acid and carrying out an ion exchange reaction to obtain a one-dimensional non-perovskite-type niobate containing hydronium ions;
3) thermally decomposing the one-dimensional non-perovskite-type niobate to obtain a one-dimensional rod-shaped Nb₂O₅;
4) using the one-dimensional rod-shaped Nb₂O₅ as template and blending with a transition metal oxide, a second alkali metal salt or alkaline earth metal salt and a second molten salt uniformly, and subjecting the mixture to a calcination process, to prepare a one-dimensional metal-doped perovskite-type niobate piezoelectric material.

27. The one-dimensional metal-doped perovskite-type niobate piezoelectric material of claim 23, wherein a molar ratio of the used amount of the niobium pentoxide, the first alkali metal salt or alkaline earth metal salt to the amount of the first molten salt in step 1) is 1: (0.01-0.8): (1-100).

28. The one-dimensional metal-doped perovskite-type niobate piezoelectric material of claim 23, wherein the acid in step 2) is hydrochloric acid, nitric acid or sulphuric acid;
and/or, the acid has a concentration of 0-10 mol/L, and is not zero;
and/or, the temperature of the ion exchange reaction in step 2) is within a range of 30-200° C., and the time is not less than 0.1 h;
and/or, the feeding ratio of the non-perovskite niobate to the acid in step 2) is 1 g: (1-2,000 mL);
and/or, the thermal decomposition temperature in step 3) is within a range of 200-1,000° C.; the time is not less than 10 min.

29. The one-dimensional metal-doped perovskite-type niobate piezoelectric material of claim 23, wherein a molar ratio of the used amount of the one-dimensional rod-shaped Nb₂O₅, the transition metal oxide, the second alkali metal salt or alkaline earth metal salt, and the second molten salt in step 4) is 1: (0.01-0.5): (0.1-50): (1-200);
and/or, the transition metal oxide in step 4) is one or more selected from the group consisting of TiO₂, Y₂O₃, SC₂O₃, ZrO₂, HfO₂, V₂O₅, Ta₂O₅, MnO₂, FezO₃, CoO₂, NiO, Ni(OH)₂, CuO₂, Al₂O₃, ZnO, Sb₂O₃, Sb₂O₅ and Bi₂O₃.

30. The one-dimensional metal-doped perovskite-type niobate piezoelectric material of claim 23, wherein the first alkali metal salt in step 1) is the same as or different from the second alkali metal salt in step 4); the alkaline earth metal salt in step 1) is the same as or different from the alkaline earth metal salt in step 4);
and/or, the first alkali metal salt or alkaline earth metal salt in step 1) and the second alkali metal salt or alkaline earth metal salt in step 4) are each independently one or more selected from the group consisting of Li₂CO₃, Na₂CO₃, K₂CO₃, CaCO₃, SrCO₃, BaCO₃, LiNO₃, NaNO₃, KNO₃, Ca(NO₃)₂, Sr(NO₃)₂ and Ba(NO₃)₂;
the first molten salt in step 1) is the same as or different from the second molten salt in step 4);
the first molten salt in step 1) and the second molten salt in step 4) are each independently selected from a mixture of halide and nitrate, or a halide, or nitrate;
and/or, the halide comprises one or more selected from the group consisting of sodium chloride, potassium chloride, cesium chloride, rubidium chloride, sodium bromide, potassium bromide, cesium bromide and rubidium bromide;
and/or, the nitrate salt comprises one or more selected from the group consisting of cesium nitrate, sodium nitrate, potassium nitrate and calcium nitrate.

31. The one-dimensional metal-doped perovskite-type niobate piezoelectric material of claim 23, wherein the mixing conditions in step 1) are the same as or different from the mixing conditions in step 4);
and/or, the liquid medium is an organic liquid or an inorganic liquid;
and/or, the calcination conditions in step 1) are the same as or different from the calcination conditions in step 4);
and/or, the calcination temperature is within a range of 200-1,200° C., the time is within the range of 1 min and 24 h.

32. The one-dimensional metal-doped perovskite-type niobate piezoelectric material of claim 23, wherein the preparation method further comprises: washing and treating the mixed and calcined product of step 1), and further comprises washing and treating the mixed and calcined product of step 4) to remove the molten salt therein.

33. A use of the one-dimensional metal-doped perovskite-type niobate piezoelectric material of claim 23 in an acoustic sensor, the acoustic sensor comprises a piezoelectric acoustic sensor.

34. A flexible acoustic sensitive device, wherein the flexible acoustic sensitive device comprise a piezoelectric acoustic sensor stimulating a mammalian cochlear outer ear hair cell array and a piezoelectric acoustic sensor film.

35. The flexible acoustic sensitive device of claim 34, where a method of preparing the piezoelectric acoustic sensor stimulating a mammalian cochlear outer ear hair cell array comprising:
(1) formulation of magnetic material ink: mixing a nanoscaled magnetic material and a polymer material uniformly under the action of an organic diluent, to obtain a magnetic material ink useful for printing a magnetic micro-cone array;
(2) printing: directly writing the magnetic material ink on the surface of a piezoelectric acoustic sensor film, to obtain a magnetic ink droplet having a certain pattern distribution, wherein the piezoelectric acoustic sensor film is prepared by using the one-dimensional metal-doped perovskite niobate piezoelectric material,
wherein the one-dimensional metal-doped perovskite-type niobate piezoelectric material has a rod-shape, and is represented by a formula ABO₃, wherein A and B are doped metals, the metal A is one or more selected from the group consisting of Bi, Li, Na, K, Ca, Sr, Ba, Cs and Rb; and the metal B is Nb and one or more selected from the group consisting of Ti, Y, Sc, Zr, Hf, V, Ta, Mn, Fe, Co, Ni, Cu, Al, Zn and Sb;
(3) magnetic field induction: placing the printed device in step (2) in a magnetic field and a high-temperature environment to subject to induction and solidification, thereby prepare flexible acoustic sensitive devices with a cone-shaped three-dimensional structure.

36. The flexible acoustic sensitive device of claim 35, wherein the organic diluent is one or more selected from the group consisting of alkanes, alcohols, ketones and amides;
and/or, the nanoscaled magnetic material is at least one of iron based/cobalt based/nickel based oxides having a magnetic property and a solid solution thereof;
and/or, the polymer material in step (1) is a curable prepolymer, including but not limited to one or more selected from the group consisting of a silicone rubber prepolymer, a self-crosslinking type polyacrylate prepolymer and a self-crosslinking type epoxy resin prepolymer;
and/or, the content of nanoscaled magnetic material is 0-80 wt %, and is not zero, based on the total weight of the ink.

37. The flexible acoustic sensitive device of claim 35, wherein the preparation method of the piezoelectric acoustic sensor film comprises the following steps:
blending the one-dimensional metal-doped perovskite niobate piezoelectric material of claim 1 with a polymer uniformly, to obtain a mixed ink that can be used for spin coating or blade coating and is composed of the one-dimensional metal-doped perovskite niobate piezoelectric material and the polymer material; a piezoelectric layer having a certain thickness is produced through spin coating, vapor deposition or blade coating; a conductive layer is disposed on a surface of the piezoelectric layer through spin coating, vapor deposition or blade coating, another surface of the piezoelectric layer is used for subsequent magnetic array printing;
wherein the polymer material is selected from curable prepolymers, including but not limited to one or more selected from the group consisting of silicone rubber prepolymer, self-crosslinking type polyacrylate prepolymer and self-crosslinking type epoxy resin prepolymer;
the content of one-dimensional metal-doped perovskite niobate piezoelectric material is 0-80 wt %, and is not zero, based on the total weight of the ink.

38. The flexible acoustic sensitive device of claim 35, wherein the conditions of direct writing comprise: an air pressure for printing is within a range of 1-70 psi, a printing speed is within a range of 0.01-50 mm/s; the magnetic ink droplet has a diameter of 50-5,000 μm;
and/or, a magnetic field strength in step (3) is within a range of 0-15 KGs and is not 0;
and/or, the curing conditions in step (3) comprise: a temperature within a range of 30-150° C., and a curing time not less than 5 minutes.

39. The flexible acoustic sensitive device of claim 34, where a method of preparing the piezoelectric acoustic sensor film comprising:
(1) mixing rod-shaped piezoelectric materials with a polymer uniformly, to obtain a mixed ink that can be used for spin coating or blade coating and is composed of piezoelectric nanorods and a polymer; wherein the rod-shaped piezoelectric material is the one-dimensional metal-doped perovskite nanorod piezoelectric material,
wherein the one-dimensional metal-doped perovskite-type niobate piezoelectric material has a rod-shape, and is represented by a formula ABO₃, wherein A and B are doped metals, the metal A is one or more selected from the group consisting of Bi, Li, Na, K, Ca, Sr, Ba, Cs and Rb; and the metal B is Nb and one or more selected from the group consisting of Ti, Y, Sc, Zr, Hf, V, Ta, Mn, Fe, Co, Ni, Cu, Al, Zn and Sb;
(2) preparing a cured piezoelectric layer through spin coating or blade coating; placing the cured piezoelectric layer in a high pressure DC voltage and high temperature environment and subjecting to polarization;
(3) preparing a patterned electrode on a surface of the polarized piezoelectric layer by using an electrode ink and the printing, vacuum evaporation and silk-screen printing process according to sensor requirement; extending the electrodes outward with a conductive filament to prepare a flexible acoustic sensitive device.
